(19) United States
(12) Patent Application Publication
(10) Pub. No.: US 2025/0321280 A1
(43) Pub. Date: Oct. 16, 2025

(54) VEHICLE CONTROL APPARATUS AND METHOD FOR ESTIMATING STATE OF CHARGE OF BATTERY

(71) Applicants: Hyundai Motor Company, Seoul (KR); Kia Corporation, Seoul (KR)

(72) Inventors: Bo Hyun Lee, Hwaseong (KR); Sang Jin Lee, Hwaseong (KR)

(21) Appl. No.: 18/887,383

(22) Filed: Sep. 17, 2024

(30) Foreign Application Priority Data
Apr. 11, 2024 (KR) 10-2024-0048806

(51) Int. Cl. G01R 31/3835; B60L 58/12; G01R 31/367; G07C 5/00; G07C 5/08; G07C 5/10

(52) U.S. Cl. CPC G01R 31/3835; G01R 31/367; G07C 5/0825; G07C 5/0833; G07C 5/085; G07C 5/10; B60L 58/12; G07C 5/008

(57) ABSTRACT

A vehicle control apparatus identifies information of a battery, estimates a first state of charge (SOC) of the battery at a first time point and a second SOC of the battery at a second time point, calculates a voltage parameter and an SOC so as to determine a profile of the battery, determines a first result for whether the first voltage parameter increases or decreases to the second voltage parameter, calculates a third voltage parameter, calculates a fourth voltage parameter, determines a second result for whether the third voltage parameter increases or decreases to the fourth voltage parameter, and compares the first result with the second result to correct the SOC.

### CROSS-REFERENCE TO RELATED APPLICATION

This application claims under 35 U.S.C. § 119(a) the benefit of Korean Patent Application No. 10-2024-0048806, filed in the Korean Intellectual Property Office on Apr. 11, 2024, the entire contents of which are incorporated herein by reference.

### BACKGROUND

### (a) Technical Field

The present disclosure relates to a vehicle control apparatus and a method thereof, and more particularly, relates to technologies for estimating a state of charge (SOC) of a battery.

### (b) Description of the Related Art

Because it is possible for a battery to be repeatedly charged and discharged, the battery is used as a power source in various fields. With the increasing spread of electric vehicles, the importance of technology associated with batteries of the electric vehicles has emerged.

There is a need to accurately measure a state of charge (SOC) of a battery to stably use the battery.

There are a current integration method, a voltage measurement method, and the like in the method for determining an SOC of the battery.

The current integration method is a method for integrating the current of the battery, which is measured in real time in the process of charging or discharging the battery, over time to estimate an SOC. In the current integration method, as an error value of a current sensor is accumulated, the accuracy of an SOC estimated over time decreases.

The voltage measurement method is a method for measuring an open circuit voltage (OCV) which flows in an open circuit to estimate an SOC. In other words, the voltage measurement method is a method for measuring an SOC of the battery and estimating the SOC of the battery, depending on an SOC table.

Meanwhile, a lithium iron phosphate (LFP) battery has a characteristic in which a change in open circuit voltage (OCV) during an appropriate usage interval of the battery is relatively smaller than other types of batteries. Thus, there is a limitation in estimating an SOC using an OCV-SOC curve.

Therefore, there is a need for a technology for more accurately estimating an SOC of the battery.

### SUMMARY

An aspect of the present disclosure provides a vehicle control apparatus for improving the accuracy of estimation of a battery state of charge (SOC) using a hysteresis characteristic of a charge voltage and a discharge voltage of a battery and a method thereof.

Another aspect of the present disclosure provides a vehicle control apparatus for overcoming a limitation which occurs to estimate an SOC of a lithium iron phosphate (LFP) battery as a change in open circuit voltage (OCV) according to the SOC is small, using a hysteresis characteristic of the OCV and a method thereof.

Another aspect of the present disclosure provides a vehicle control apparatus for correcting an error which occurs in an SOC of a battery, which is estimated in a current integration method, using a hysteresis characteristic of an OCV and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a vehicle control apparatus may include a memory storing a program instruction and a processor that executes the program instruction. The processor may identify information of a battery of a vehicle, the information including at least one of a charge current of the battery, a discharge current of the battery, a charge voltage of the battery, a discharge voltage of the battery, or a temperature of the battery, may estimate a first state of charge (SOC) of the battery at a first time point and a second SOC of the battery at a second time point when a certain time elapses from the first time point, based on the information of the battery, may calculate a voltage parameter and an SOC according to a hysteresis characteristic of a charge voltage and a discharge voltage, so as to determine a profile of the battery, may identify a first voltage parameter, based on the profile and the first SOC, may identify a second voltage parameter, based on the profile and the second SOC, may determine a first result for whether the first voltage parameter increases or decreases to the second voltage parameter, may calculate a third voltage parameter according to the hysteresis characteristic of the battery, using the charge voltage at the first time point and the discharge voltage at the first time point, may calculate a fourth voltage parameter according to the hysteresis characteristic of the battery, using the charge voltage at the second time point and the discharge voltage at the second time point, may determine a second result for whether the third voltage parameter increases or decreases to the fourth voltage parameter, and may compare the first result with the second result and may correct at least one of the first SOC or the second SOC.

In an embodiment, the processor may correct the at least one of the first SOC or the second SOC, or the any combination thereof, based on determination that the first result and the second result are different from each other.

In an embodiment, the processor may correct the at least one of the first SOC or the second SOC, or the any combination thereof to be determined that the first result and the second result are the same as each other.

In an embodiment, the profile may include information in which the SOC and the voltage parameter match with each other. The processor may identify a point at which a change rate of the voltage parameter according to the SOC is 0, based on the information in which the SOC and the voltage parameter match with each other.

In an embodiment, the processor may identify at least one third SOC corresponding to the point at which the change rate of the voltage parameter according to the SOC is 0 among a plurality of SOCs included in the profile and may determine the first result, based on that the third SOC is not included between the first SOC and the second SOC.

In an embodiment, the processor may update the profile based on the information of the battery.

In an embodiment, the processor may update a point at which a change rate of the voltage parameter according to the SOC is 0 among points included in the profile, based on the information of the battery.

In an embodiment, the processor may identify the charge voltage or the discharge voltage, based on an open circuit voltage (OCV).

In an embodiment, the battery may include a lithium iron phosphate (LFP) battery.

According to another aspect of the present disclosure, a vehicle may include the above-described vehicle control apparatus.

In an embodiment, the processor may store the profile in at least one of the memory, a storage device of the vehicle, the storage device being different from the memory, or an external server.

In an embodiment, the processor may provide a user with information about at least one of the corrected first SOC or the corrected second SOC, by means of at least one of a display of the vehicle or an audio of the vehicle.

According to a further aspect of the present disclosure, a vehicle control method may include identifying, by a processor, information of a battery of a vehicle, the information including at least one of a charge current of the battery, a discharge current of the battery, a charge voltage of the battery, a discharge voltage of the battery, or a temperature of the battery, estimating, by the processor, a first state of charge (SOC) of the battery at a first time point and a second SOC of the battery at a second time point when a certain time elapses from the first time point, based on the information of the battery, calculating, by the processor, a voltage parameter and an SOC according to a hysteresis characteristic of a charge voltage and a discharge voltage, so as to determine a profile of the battery, identifying, by the processor, the first voltage parameter, based on the profile and the first SOC, identifying, by the processor, a second voltage parameter, based on the profile and the second SOC, determining, by the processor, a first result for whether the first voltage parameter increases or decreases to the second voltage parameter, calculating, by the processor, a third voltage parameter according to the hysteresis characteristic of the battery, using the charge voltage at the first time point and the discharge voltage at the first time point, calculating, by the processor, a fourth voltage parameter according to the hysteresis characteristic of the battery, using the charge voltage at the second time point and the discharge voltage at the second time point, determining, by the processor, a second result for whether the third voltage parameter increases or decreases to the fourth voltage parameter, and comparing, by the processor, the first result with the second result and correcting, by the processor, at least one of the first SOC or the second SOC.

In the vehicle control method according to an embodiment, the comparing of the first result with the second result by the processor and the correcting of the at least one of the first SOC or the second SOC, or the any combination thereof by the processor may include correcting, by the processor, the at least one of the first SOC or the second SOC, or the any combination thereof, based on determination that the first result and the second result are different from each other.

In the vehicle control method according to an embodiment, the comparing of the first result with the second result by the processor and the correcting of the at least one of the first SOC or the second SOC, or the any combination thereof by the processor may include correcting, by the processor, the at least one of the first SOC or the second SOC, or the any combination thereof to be determined that the first result and the second result are the same as each other.

In the vehicle control method according to an embodiment, the determining of the first result for whether the first voltage parameter increases or decreases to the second voltage parameter by the processor may include identifying, by the processor, a point at which a change rate of the voltage parameter according to the SOC is 0, based on information in which the SOC and the voltage parameter match with each other, the information being included in the profile.

In the vehicle control method according to an embodiment, the determining of the first result for whether the first voltage parameter increases or decreases to the second voltage parameter by the processor may include identifying, by the processor, at least one third SOC corresponding to the point at which the change rate of the voltage parameter according to the SOC is 0 among a plurality of SOCs included in the profile and determining, by the processor, the first result, based on that the third SOC is not included between the first SOC and the second SOC.

The vehicle control method according to an embodiment may further include updating, by the processor, the profile based on the information of the battery.

In the vehicle control method according to an embodiment, the updating of the profile based on the information of the battery by the processor may include updating, by the processor, a point at which a change rate of the voltage parameter according to the SOC is 0 among points included in the profile, based on the information of the battery.

In the vehicle control method according to an embodiment, the identifying of the information of the battery of the vehicle, the information including the at least one of the charge current of the battery, the discharge current of the battery, the charge voltage of the battery, the discharge voltage of the battery, or the temperature of the battery, or the any combination thereof by the processor may include identifying, by the processor, the charge voltage or the discharge voltage, based on an open circuit voltage (OCV).

The vehicle control method according to an embodiment may further include storing, by the processor, the profile in at least one of a memory, a storage device of the vehicle, the storage device being different from the memory, or an external server.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating a vehicle control apparatus according to an embodiment of the present disclosure;

FIG. 2 is a graph illustrating an example of a hysteresis characteristic according to charging or discharging of a battery, in conjunction with a vehicle control apparatus according to an embodiment of the present disclosure;

FIG. 3 is a drawing illustrating an example of matching an SOC according to an SOC-voltage parameter (M_0) graph with an SOC according to an SOC-OCV graph of a battery, in conjunction with a vehicle control apparatus according to an embodiment of the present disclosure;

FIG. 4 is a flowchart for describing a vehicle control apparatus or a vehicle control method according to an embodiment of the present disclosure;

FIG. 5 is a flowchart for describing in detail an example of a process of determining whether there is a need to correct an estimated SOC, in a vehicle control apparatus or a vehicle control method according to an embodiment of the present disclosure;

FIG. 6 is a drawing for describing an example of a method for comparing change rates of a voltage parameter in a vehicle control apparatus according to an embodiment of the present disclosure; and

FIG. 7 is a drawing illustrating a computing system associated with a vehicle control apparatus or a vehicle control method according to an embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Hereinafter, some embodiments of the present disclosure will be described in detail with reference to the exemplary drawings. In adding the reference numerals to the components of each drawing, it should be noted that the identical component is designated by the identical numerals even when they are displayed on other drawings. In addition, a detailed description of well-known features or functions will be ruled out in order not to unnecessarily obscure the gist of the present disclosure.

In describing components of exemplary embodiments of the present disclosure, the terms first, second, A, B, (a), (b), and the like may be used herein. These terms are only used to distinguish one component from another component, but do not limit the corresponding components irrespective of the order or priority of the corresponding components. Particularly, the expression “at least one of A, B, or C, or any combination thereof” may include “A”, “B”, or “C”, or “AB”, “BC”, “AC”, or “ABC”, which is a combination thereof.

Furthermore, unless otherwise defined, all terms including technical and scientific terms used herein have the same meaning as being generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

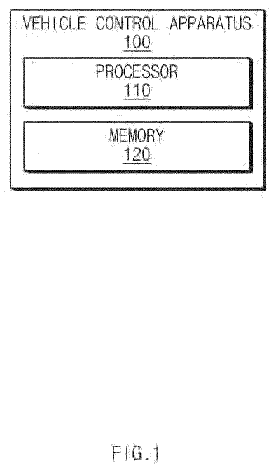

Hereinafter, embodiments of the present disclosure will be described in detail with reference to FIGS. 1 to 7.

FIG. 1 is a block diagram illustrating a vehicle control apparatus according to an embodiment of the present disclosure.

Referring to FIG. 1, a vehicle control apparatus 100 according to an embodiment of the present disclosure may be implemented in a vehicle. In this case, the vehicle control apparatus 100 may be integrally configured with control units in the vehicle or may be implemented as a separate device to be connected with the control units of the vehicle by a separate connection means.

According to an embodiment, the vehicle control apparatus 100 may include a processor 110 and a memory 120. The components of the vehicle control apparatus 100, which are shown in FIG. 1, are illustrative, and embodiments of the present disclosure are not limited thereto. For example, the vehicle control apparatus 100 may further include components which are not shown in FIG. 1.

According to an embodiment, the memory 120 may store a command or data. For example, the memory 120 may store one instruction or two or more instructions, when executed by the processor 110, causing the vehicle control apparatus 100 to perform various operations.

According to an embodiment, the memory 120 may be implemented with the processor 110 as one chipset and may store various pieces of information associated with the vehicle control apparatus 100. For example, the memory 120 may store information about an operation history of the processor 110.

According to an embodiment, the memory 120 may include a non-volatile memory (e.g., a read only memory (ROM)) and a volatile memory (e.g., a random access memory (RAM)). For example, an SOC of the battery and a voltage parameter, which are calculated by the processor 110, may be stored in the memory 120.

According to an embodiment, the processor 110 may identify information of the battery of the vehicle, which includes at least one of a charge current of the battery, a discharge current of the battery, a charge voltage of the battery, a discharge voltage of the battery, or a temperature of the battery, or any combination thereof.

According to an embodiment, the processor 110 may identify a current charged in the battery or a current discharged from the battery, by means of a current sensor. For example, the processor 110 may identify a value of the charge current or a value of the discharge current, which is measured by means of the current sensor.

According to an embodiment, the processor 110 may identify a voltage charged in the battery or a voltage discharged from the battery, by means of a voltage sensor. For example, the processor 110 may identify a value of the charge voltage or a value of the discharge voltage, which is measured by means of the voltage sensor.

According to an embodiment, the processor 110 may identify a temperature of the battery, by means of a temperature sensor.

According to an embodiment, the information of the battery, which is capable of being identified by the processor 110, may include various pieces of information other than the current, the voltage, or the temperature. For example, the information of the battery may include capacity of the battery, life of the battery, charge efficiency of the battery, a charging speed of the battery, a discharging speed of the battery, a charge and discharge cycle of the battery, or the like.

According to an embodiment, the processor 110 may estimate a first state of charge (SOC) of the battery at a first time point and a second SOC of the battery at a second time point when a certain time elapses from the first time point, based on the information of the battery.

According to an embodiment, the processor 110 may estimate an SOC of the battery in various methods. The SOC estimated by the processor 110 may be estimated as a percentage value of 0% or more or 100% or less or may be estimated as a rate value of 0 or more and 1 or less.

For example, the processor 110 may estimate an SOC of the battery, using a current integration method. In detail, the current integration method may include a method for integrating the current of the battery, which is measured in real time in the process of charging or discharging the battery to estimate an SOC.

For another example, the processor 110 may estimate an SOC of the battery, using a voltage measurement method. In detail, the voltage measurement method may include a method for measuring a voltage value compared to remaining capacity of the battery and estimating an SOC. Alternatively, the voltage measurement method may include a method for measuring an open circuit voltage (OCV) which flows in an open circuit and estimating an SOC.

For another example, the processor 110 may estimate an SOC of the battery, using a chemometric method. In detail, the processor 110 may measure gravity or acidity (pH) of electrolyte of the battery and may estimate an SOC of the battery.

For another example, the processor 110 may estimate an SOC of the battery, using a pressure measurement method. In detail, the processor 110 may measure internal pressure of the battery and may estimate an SOC of the battery.

According to an embodiment, the processor 110 may estimate an SOC at a specific time point. For example, the processor 110 may estimate the first SOC at the first time point and may estimate the second SOC at the second time point when the certain time elapses from the first time point. The first time point may include a current time point, and the second time point may include the time point when the certain time elapses from the first time point.

According to an embodiment, a certain time interval between the first time point and the second time point may be preset by a system or a user. For example, the certain time interval between the first time point and the second time point may be set to a time when it is able to identify a change in SOC of the battery.

As a detailed example, if the certain time interval is 3 seconds, the processor 110 may estimate an SOC (or the first SOC) at the current time point (or the first time point) and may estimate an SOC (or the second SOC) at a time point (or the second time point) after 3 seconds from the current time point.

According to an embodiment, the processor 110 may identify a profile in which a voltage parameter and an SOC of the battery, which are calculated according to a hysteresis characteristic of a charge voltage and a discharge voltage, which are identified in a process in which the battery of the vehicle is charged or discharged, before the first time point are reflected.

According to an embodiment, the profile may indicate a collection of data including various pieces of data. For example, the profile may include data about the voltage parameter and data about the SOC of the battery in various manners. As a detailed example, the data about the voltage parameter and the data about the SOC of the battery may be reflected in the profile in a manner, such as a graph, a chart, a scatter plot, or a histogram.

According to an embodiment, the profile may include data in which the SOC and the voltage parameter match with each other. For example, the voltage parameter calculated in the process in which the battery of the vehicle was charged or discharged in the past may correspond to the SOC of the battery. Thus, the profile may include data about the voltage parameter corresponding to each SOC.

According to an embodiment, the profile may include pieces of data identified in the process in which the battery of the vehicle was charged or discharged in the past. Herein, the past may refer to a time point before the current time point when the SOC is estimated, which may include a time point before the first time point. For example, the profile may include pieces of data accumulated in the process in which the battery of the vehicle is charged or discharged. For example, the processor 110 may update pieces of data identified in the process in which the battery of the vehicle is charged or discharged in the profile.

According to an embodiment, the voltage parameter may be calculated according to a hysteresis characteristic of the charge voltage of the battery and the discharge voltage of the battery.

According to an embodiment, the hysteresis characteristic may include a characteristic showing a delay or change for a change in external factor. For example, the hysteresis characteristic associated with voltage may include that the current voltage changes based on a change in voltage in the past.

For example, the voltage parameter may be calculated as an average value of the charge voltage and the discharge voltage. For example, the voltage parameter may be calculated as an average value of the charge voltage and the discharge voltage in the same SOC. For another example, the voltage parameter may be calculated as an average value of the charge voltage and the discharge voltage at the same time point. This is only an embodiment. The voltage parameter may be calculated as a value for a difference between the charge voltage and the discharge voltage or may be calculated as an intermediate value.

According to an embodiment, the charge voltage and the discharge voltage may include an open circuit voltage (OCV). Thus, the voltage parameter may be calculated as an average value of a charge OCV and a discharge OCV or a value for a difference between the charge OCV and the discharge OCV.

For example, the voltage parameter may be calculated by Equation 1 or 2 below.

$${M}_{0} = \frac{\vert Charge OCV \vert + \vert Discharge OCV \vert}{2} \qquad [ Equation 1 ]$$

According to an embodiment, based on Equation 1 above, the voltage parameter M₀ may be calculated as a value obtained by dividing the sum of an absolute value of the charge OCV and an absolute value of the discharge OCV by 2.

$${M}_{0} = \frac{Charge OCV - Discharge OCV}{2} \qquad [ Equation 2 ]$$

According to an embodiment, based on Equation 2 above, the voltage parameter M₀ may be calculated as a value obtained by dividing a difference between a value of the charge OCV and a value of the discharge OCV by 2.

According to an embodiment, the processor 110 may identify a first voltage parameter, based on the profile and the first SOC. The profile may include data about the voltage parameter corresponding to the SOC of the battery.

For example, the processor 110 may identify an SOC at the first time point as the first SOC and may identify a voltage parameter corresponding to the first SOC among pieces of data of the profile as the first voltage parameter.

As a detailed example, if the first SOC at the first time point is 41%, the processor 110 may identify the first voltage parameter with a value of 0.038, which corresponds to the first SOC of 41%, among the pieces of data of the profile. As a result, if there is no error in the estimated SOC, it may be seen that the voltage parameter with the value of 0.038 should be calculated in the SOC of 41%.

According to an embodiment, the processor 110 may identify a second voltage parameter, based on the profile and the second SOC.

For example, the processor 110 may identify an SOC at the second time point as the second SOC and may identify a voltage parameter corresponding to the second SOC among the pieces of data of the profile as the second voltage parameter. Herein, the second time point may include the time point when the certain time elapses from the first time point.

As a detailed example, if the second SOC at the second time point is 43%, the processor 110 may identify the first voltage parameter with a value of 0.040, which corresponds to the first SOC of 43%, among the pieces of data of the profile. As a result, if there is no error in the estimated SOC, it may be seen that the voltage parameter with the value of 0.040 should be calculated in the SOC of 43%.

According to an embodiment, the processor 110 may determine a first result for whether the first voltage parameter increases or decreases to the second voltage parameter.

For example, as the first SOC at the first time point changes to the second SOC at the second time point, the processor 110 may determine whether the voltage parameter increases or decreases.

As a detailed example, if the first voltage parameter is identified as 0.038 and the second voltage parameter is identified as 0.040, while time elapses from the first time point to the second time point, the processor 110 may determine that the voltage parameter increases. Thus, the processor 110 may determine that the voltage parameter increases, as the first result.

According to an embodiment, the processor 110 may calculate a voltage parameter, using a charge voltage and a discharge voltage of the battery, which are identified at a specific time point.

For example, the charge voltage and the discharge voltage at the same time point may be differently identified, according to a voltage hysteresis characteristic. Thus, the processor 110 may calculate a voltage parameter, using the charge voltage and the discharge voltage. The charge voltage and the discharge voltage, which are identified at each time point, may include an open circuit voltage (OCV).

According to an embodiment, the processor 110 may calculate a third voltage parameter according to the hysteresis characteristic of the battery, using the charge voltage at the first time point and the discharge voltage at the first time point. At this time, the first time point may be understood as the same time point as a time point when the first SOC is previously estimated. In other words, the processor 110 may calculate the third voltage parameter using the charge voltage at the first time point and the discharge voltage at the first time point, at the same time as estimating the SOC, at the first time point.

For example, the processor 110 may calculate an average value of the charge SOC at the first time point and the discharge OCV at the first time point as the third voltage parameter. In other words, based on Equation 1 or 2 described above, the third voltage parameter may be calculated as a value obtained by dividing the sum of an absolute value of the charge OCV at the first time point and an absolute value of the discharge OCV at the second time point by 2.

According to an embodiment, the processor 110 may calculate a fourth voltage parameter according to the hysteresis characteristic of the battery, using the charge voltage at the second time point and the discharge voltage at the second time point. At this time, the second time point may be understood as the same time point as a time point when the second SOC is previously estimated. In other words, the processor 110 may calculate a fourth voltage parameter using the charge voltage at the second time point and the discharge voltage at the second time point, at the same time as estimating the SOC, at the second time point.

For example, the processor 110 may calculate an average value of the charge SOC at the second time point and the discharge OCV at the second time point as the fourth voltage parameter. In other words, based on Equation 1 or 2 described above, the fourth voltage parameter may be calculated as a value obtained by dividing the sum of an absolute value of the charge OCV at the second time point and an absolute value of the discharge OCV at the second time point by 2.

According to an embodiment, the processor 110 may determine a second result for whether the third voltage parameter increases or decreases to the fourth voltage parameter.

For example, it may be seen that the voltage parameter with the value of 0.038 should be calculated in the SOC of 41%.

According to an embodiment, the processor 110 may identify the second voltage parameter, based on the profile and the second SOC.

For example, the processor 110 may identify an SOC at the second time point as the second SOC and may identify a voltage parameter corresponding to the second SOC among the pieces of data of the profile as the second voltage parameter. Herein, the second time point may include the time point when the certain time elapses from the first time point.

As a detailed example, if the second SOC at the second time point is 43%, the processor 110 may identify the first voltage parameter with a value of 0.040, which corresponds to the first SOC of 43%, among the pieces of data of the profile. As a result, if there is no error in the estimated SOC, it may be seen that the voltage parameter with the value of 0.040 should be calculated in the SOC of 43%.

According to an embodiment, the processor 110 may determine the second result for whether the third voltage parameter increases or decreases to the fourth voltage parameter.

For example, the processor 110 may compare the third voltage parameter calculated at the first time point with the fourth voltage parameter calculated at the second time point and may determine whether the voltage parameter increases or decreases as time elapses from the first time point to the second time point.

As a detailed example, if the third voltage parameter with a value of 0.037 is calculated and the fourth voltage parameter with a value of 0.035 is calculated, while time elapses from the first time point to the second time point, the processor 110 may determine that the voltage parameter decreases. Thus, the processor 110 may determine that the voltage parameter decreases, as the second result.

According to an embodiment, the processor 110 may compare the first result with the second result.

For example, the first result may include determination for whether the voltage parameter corresponding to the estimated SOC increases or decreases as time elapses from the first time point and the second time point. The second result may include determination for whether the voltage parameter calculated using the charge voltage and the discharge voltage increases or decreases as time elapses from the first time point to the second time point.

In other words, the voltage parameter included in the first result may refer to a voltage parameter corresponding to an SOC estimated at each time point, whereas the voltage parameter included in the second result may refer to a voltage parameter calculated using a charge voltage and a discharge voltage identified at each time point.

According to an embodiment, the processor 110 may determine whether the first result and the second result are the same as or different from each other. For example, if the first result is a result determined that the voltage parameter increases and the second result is a result determined that the voltage parameter decreases, the processor 110 may determine that the first result and the second result are different from each other. Conversely, for example, if both the first result and the second result are results determined that the voltage parameter increases, the processor 110 may determine that the first result and the second result are the same as each other.

According to an embodiment, the processor 110 may compare the first result with the second result and may correct the estimated SOC, if it is determined that the first result and the second result are different from each other. Herein, the SOC to be corrected may include at least one of the first SOC or the second SOC, or any combination thereof.

According to an embodiment, the processor 110 may correct at least one of the first SOC or the second SOC, or any combination thereof to be determined that the first result and the second result are the same as each other.

For example, if it is determined that the first result and the second result are different from each other, the processor 110 may determine that there is an error in the estimated SOC. In light of the fact that an error may occur over time in the SOC estimated by the current integration method or the like, the second result about the voltage parameter calculated using the charge voltage and the discharge voltage of the battery may be determined as a result more consistent with an actual SOC than the first result about the voltage parameter corresponding to the estimated SOC. Thus, if it is determined that the first result and the second result are different from each other, the processor 110 may correct the SOC depending on the second result.

For example, if the first result is a result determined that the voltage parameter increases and the second result is a result determined that the voltage parameter decreases, the processor 110 may correct the estimated SOC, such that the first result is the result determined that the voltage parameter decreases. As a detailed example, the processor 110 may increase or decrease the estimated SOC to be determined that the voltage parameter corresponding to the estimated SOC decreases.

According to an embodiment, the profile may include information in which the SOC and the voltage parameter match with each other. The processor 110 may identify a point at which a change rate of the voltage parameter according to the SOC is 0, based on the information in which the SOC and the voltage parameter match with each other.

According to an embodiment, the processor 110 may calculate a change rate of the voltage parameter according to the SOC, based on the information in which the SOC and the voltage parameter match with each other, which is included in the profile. The processor 110 may identify a point at which the change rate among the calculated change rates of the voltage parameter according to the SOC is 0.

As a detailed example, the information in which the SOC and the profile match with each other may be included in the profile in the form of a graph. The profile may include an “SOC-voltage parameter graph”, the horizontal axis of which is the SOC and the vertical axis of which is the voltage parameter. In this case, the processor 110 may identify a point at which the slope is 0 in an “SOC-voltage parameter” as the point at which the change rate of the voltage parameter according to the SOC is 0.

According to an embodiment, the profile may include two or more points at which the change rate of the voltage parameter according to the SOC is 0. The state of the change rate of the voltage parameter according to the SOC may switch with respect to the point at which the change rate of the voltage parameter according to the SOC is 0. For example, if the change rate of the voltage parameter according to the SOC is represented as a slope, a sign of the slope may vary before and after the point at which the slope is 0.

According to an embodiment, the processor 110 may identify at least one third SOC, corresponding to the point at which the change rate of the voltage parameter according to the SOC is 0, among SOCs included in the profile. For example, the processor 110 may identify an SOC, corresponding to the point at which the slope of the voltage parameter according to the SOC is 0, in the profile as the third SOC. The sign of the slope of the voltage parameter may vary before and after the third SOC.

According to an embodiment, the processor 110 may determine the first result, based on that the third SOC is not included between the first SOC and the second SOC. If the third SOC is included between the first SOC and the second SOC, the processor 110 may fail to accurately determine whether the voltage parameter corresponding to the estimated SOC increases or decreases, depending on that the certain time elapses from the first time point and the second time point.

For example, the voltage parameter corresponding to the estimated SOC may increase from the first SOC to the third SOC, and the voltage parameter corresponding to the estimated SOC may decrease from the third SOC to the second SOC. In this case, both of an interval in which the voltage parameter corresponding to the estimated SOC increases and an interval in which the voltage parameter corresponding to the estimated SOC decreases may be included between the first SOC and the second SOC.

Conversely, if the third SOC is not included between the first SOC and the second SOC, only the interval in which the voltage parameter corresponding to the estimated SOC increases or only the interval in which the voltage parameter corresponding to the estimated SOC decreases may be included between the first SOC and the second SOC.

In other words, only if the third SOC is not included between the first SOC and the second SOC, the processor 110 may compare the first result with the second result to determine whether there is a need to correct the estimated SOC.

Thus, only if the third SOC is not included between the first SOC and the second SOC, the processor 110 may determine the first result and may compare the first result with the second result.

According to an embodiment, the processor 110 may update the profile based on the information of the battery. In detail, the processor 110 may update data, such as the SOC of the battery and the voltage parameter, which is included in the profile, using the charge current of the battery of the vehicle, the discharge current of the battery, the charge voltage of the battery, the discharge voltage of the battery, the temperature of the battery, or the like.

According to an embodiment, the processor 110 may update the point at which the change rate of the voltage parameter according to the SOC is 0 among the points included in the profile, based on the information of the battery. For example, pieces of data associated with the SOC of the battery and the voltage parameter, which are included in the profile, may be updated based on the information of the battery. Thus, the point at which the change rate of the voltage parameter according to the SOC is 0 may also be updated.

According to an embodiment, the processor 110 may identify the updated point at which the change rate of the voltage parameter according to the SOC is 0. For example, the processor 110 may update the third SOC, based on that the point at which the change rate of the voltage parameter according to the SOC is 0 is updated. The processor 110 may determine the first result, based on that the updated third SOC is not included between the first SOC and the second SOC.

According to an embodiment, the processor 110 may identify a charge voltage or a discharge voltage, based on the open circuit voltage (OCV). As described above, the charge voltage or the discharge voltage identified by the processor 110 may include the OCV.

For example, the OCV may refer to a voltage in a state in which the circuit is open, if measuring a voltage between two terminals of the battery. In other words, the OCV may refer to a voltage if current does not flow to an external circuit. As the battery is charged, the OCV may increase. As the battery is discharged, the OCV may decrease.

The battery according to an embodiment may include a lithium iron phosphate (LFP) battery. However, this is only an embodiment, and the battery may include various types of batteries. For example, the battery may include a nickel cobalt aluminum (NCA) battery, a nickel cobalt manganese (NCM) battery, a lithium cobalt oxide (LCO) battery, or a lithium manganese oxide (LMO) battery.

According to an embodiment, the processor 110 may store the profile in at least one of the memory 120, a storage device of the vehicle, which is different from the memory 120, or an external server, or any combination thereof. A medium capable of storing the profile may vary, and the profile may be stored in various databases.

The display of the vehicle may include at least one of a cluster, a head up display (HUD), a center information display (CID), a co-driver display (CDD), a side mirror display, or a rear seat entertainment display, or any combination thereof.

For example, if the profile is stored in the external server, the processor 110 may download the profile stored in the server using a communication circuit (not shown) or may update the profile stored in the server using the communication circuit.

According to an embodiment, the communication circuit may include a circuit for wireless Internet access. For example, the communication circuit may access a wireless communication network of a wireless communication operator to use wireless communication such as third generation mobile communications (3G), long term evolution (LTE), LTE-Advanced (LTE-A), or fifth generation mobile communications (5G). Furthermore, the communication circuit may be loaded into a telematics unit and may include a radio frequency (RF) antenna and a communication control module.

According to an embodiment, the processor 110 may provide the user with information about at least one of the corrected first SOC or the corrected second SOC, or any combination thereof, by means of at least one of the display of the vehicle or an audio of the vehicle, or any combination thereof.

For example, the processor 110 may provide the user with information about the corrected SOC. The corrected SOC may include the corrected first SOC and the corrected second SOC. The user may receive the information about the corrected SOC to receive information about a more accurate SOC.

According to an embodiment, the processor 110 may provide the information about the corrected SOC by means of a terminal of the user. The processor 110 may transmit the information about the corrected SOC to the terminal of the user via the communication circuit. The user may check the information about the SOC even outside the vehicle using the terminal.

According to an embodiment, the processor 110 may control the vehicle, based on the SOC of the battery of the vehicle. The processor 110 may control the vehicle based on the corrected SOC. For example, the processor 110 may control the vehicle, such that fuel efficiency or fuel economy of the vehicle is improved, based on the corrected SOC.

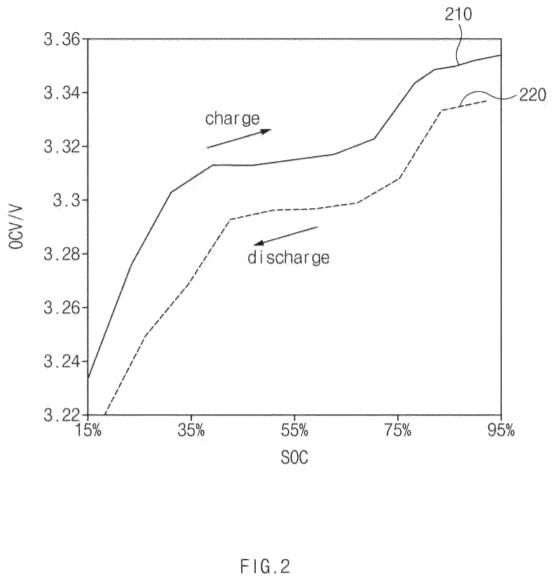

FIG. 2 is a graph illustrating an example of a hysteresis characteristic according to charging or discharging of a battery, in conjunction with a vehicle control apparatus according to an embodiment of the present disclosure.

FIG. 2 according to an embodiment is a graph illustrating an example of a hysteresis characteristic of a voltage measured in a process of charging or discharging a battery.

In the graph of FIG. 2 according to an embodiment, the horizontal axis may indicate an SOC and the vertical axis may indicate an open circuit voltage (OCV). Herein, the OCV may be replaced with a voltage of the battery.

According to an embodiment, the graph of FIG. 2 may include a trend line 210 of a charge voltage and a trend line 220 of a discharge voltage. Because the voltage of the battery has a hysteresis characteristic, a charge voltage and a discharge voltage corresponding to the same SOC may be differently measured.

According to an embodiment, the hysteresis characteristic shown in FIG. 2 may be differently represented for each type of the battery. For example, for an LFP battery, the trend line of the charge voltage and the trend line of the discharge voltage due to the hysteresis characteristic may be shown to be different from FIG. 2. As a detailed example, for the LFP battery, the OCV may be generally constantly shown in an interval between an SOC of about 5% and an SOC of about 95%.

Referring to FIG. 2 according to an embodiment, the charge voltage and the discharge voltage may be differently measured in the same SOC by the hysteresis characteristic. To identify a voltage of the battery, which corresponds to the SOC, there may be a need to calculate an average value or an intermediate value between the charge voltage and the discharge voltage. At this time, the average value or the intermediate value between the charge voltage and the discharge voltage may be defined as a voltage parameter in the specification. For example, the voltage parameter may be calculated by Equation 1 or 2 described above.

Referring to FIG. 2 according to an embodiment, there is a need to consider the voltage hysteresis characteristic, in estimating or correcting the SOC of the battery.

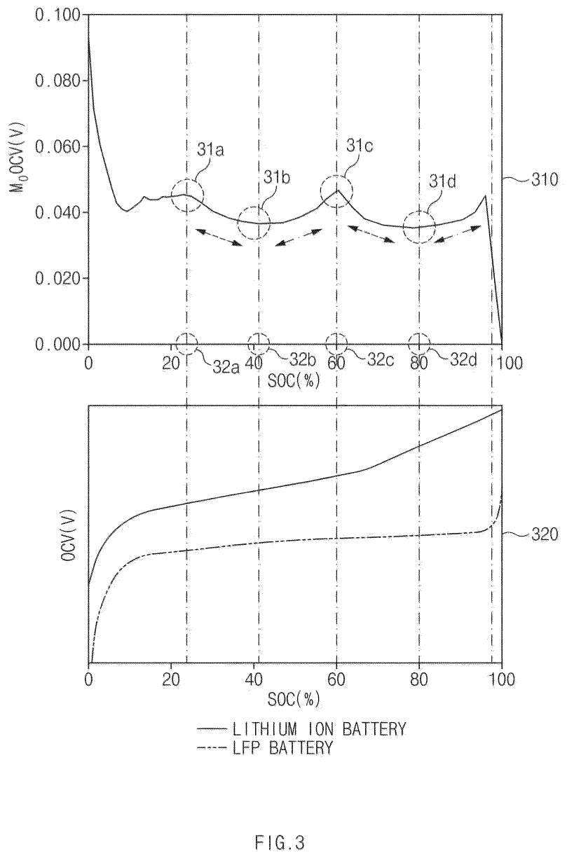

FIG. 3 is a drawing illustrating an example of matching an SOC according to an SOC-voltage parameter (M₀) graph with an SOC according to an SOC-OCV graph of a battery, in conjunction with a vehicle control apparatus according to an embodiment of the present disclosure.

FIG. 3 according to an embodiment may include an SOC-voltage parameter (M₀) graph 310 and an SOC-OCV graph 320 of a battery.

According to an embodiment, in the SOC-voltage parameter (M₀) graph 310, the horizontal axis may indicate an SOC and the vertical axis may indicate a voltage parameter M₀. The SOC-voltage parameter (M₀) graph 310 may include a trend line of the voltage parameter M₀.

According to an embodiment, the SOC-OCV graph 320 of the battery, the horizontal axis may indicate an SOC and the vertical axis may indicate an open circuit voltage (OCV). The SOC-OCV graph 320 of the battery may include a trend line of the OCV of a lithium ion battery and a trend line of the OCV of an LFP battery.

Referring to the SOC-OCV graph 320 of the battery in FIG. 3 according to an embodiment, in a range from an SOC of about 10% to an SOC of about 95%, a change rate of the OCV of the LFP battery may be shown to be smaller than the change rate of the OCV of the lithium ion battery. Thus, for the LFP battery, it may be difficult to identify a change in OCV corresponding to the SOC. Thus, for the LFP battery, a change in the OCV corresponding to the SOC may be identified by means of the voltage parameter M₀.

In the SOC-voltage parameter (M₀) graph 310 according to an embodiment, a change rate of the voltage parameter M₀ may be identified. In detail, the change rate of the voltage parameter M₀ may be identified using a slope of a trend line of the voltage parameter M₀.

In the SOC-voltage parameter (M₀) graph 310 according to an embodiment, a point at which the slope of the trend line of the voltage parameter M₀ is 0 may be identified. For example, the point at which the slope of the trend line of the voltage parameter M₀ is 0 may be identified as two or more points. As a detailed example, in the SOC-voltage parameter (M₀) graph 310 of FIG. 3, point 31a, 31b, 31c, or 31d may be identified as the point at which the slope of the trend line of the voltage parameter M₀ is 0. However, this is only an embodiment, and the point at which the slope of the trend line of the voltage parameter M₀ is 0 may be identified, other than points 31a, 31b, 31c, and 31d.

According to an embodiment, an SOC corresponding to the point at which the slope of the trend line of the voltage parameter M₀ is 0 may be identified. For example, the SOC at point 32a may correspond to point 31a, the SOC at point 32b may correspond to point 31b, the SOC at point 32c may correspond to point 31c, and the SOC at point 32d may correspond to point 31d.

According to an embodiment, the entire SOC range may be divided into a plurality of SOC intervals on the basis of an SOC of the point corresponding to the point at which the slope of the trend line of the voltage parameter M₀ is 0. For example, the plurality of SOC intervals may include a first interval from point 32a to point 32b, a second interval from point 32b to point 32c, and a third interval from point 32c to point 32d. This is only an embodiment, and the plurality of SOC intervals may further include a plurality of intervals other than the first to third intervals.

According to an embodiment, the SOC and the voltage parameter M₀ may fail to be proportional to each other.

For example, the voltage parameter M₀ may increase, as the SOC increases in a specific interval, and the voltage parameter M₀ may decrease, as the SOC increases in another specific interval.

As a detailed example, the voltage parameter M₀ may decrease, as the SOC increases in the first interval, and the voltage parameter M₀ may increase, as the SOC increases in the second interval.

According to an embodiment, the slope of the trend line of the voltage parameter M₀ may switch on the basis of the point at which the slope of the trend line of the voltage parameter M₀ is 0.

For example, the slope of the trend line of the voltage parameter M₀ may be identified as a negative number in the first interval on the basis of point 31b, whereas the slope of the trend line of the voltage parameter M₀ may be identified as a positive number in the second interval on the basis of point 31b. Likewise, the slope of the trend line of the voltage parameter M₀ may be identified as a positive number in the second interval on the basis of point 31c, whereas the slope of the trend line of the voltage parameter M₀ may be identified as a negative number in the third interval on the basis of point 31c.

The SOC-voltage parameter (M₀) graph 310 of FIG. 3 according to an embodiment may be understood together with the above-mentioned description of FIG. 1.

For example, pieces of data included in the profile described with reference to FIG. 1 may be illustrated as the SOC-voltage parameter (M₀) graph 310 of FIG. 3.

For example, if a first SOC estimated at a first time point by a processor 110 of FIG. 1 and a second SOC estimated at a second time point by the first processor 110 belong to a range of the first interval and the first SOC increases to the second SOC, the processor 110 may determine a first result in which the voltage parameter decreases from a first voltage parameter to a second voltage parameter.

The processor 110 may calculate a third voltage parameter using a charge voltage and a discharge voltage at the first time point and may calculate a fourth voltage parameter using a charge voltage and a discharge voltage at the second time point. If the fourth voltage parameter is greater than the third voltage parameter, the processor 110 may determine a second result in which the voltage parameter increases from the third voltage parameter to the fourth voltage parameter.

In this case, because the first result and the second result are different from each other, the processor 110 may determine that there is a need to correct an estimated SOC.

For example, if the processor 110 of FIG. 1 updates the profile, based on information of the battery, the point at which the slope of the trend line of the voltage parameter M₀ is 0 may also be updated. In detail, as the profile is updated, at least one of point 31a, point 31b, point 31c, or point 31d, or any combination thereof may also be updated.

Referring to FIG. 3 according to an embodiment, if it is difficult to identify a change in OCV corresponding to the SOC, like the LFP battery, the processor 110 may identify the change in OCV corresponding to the SOC by means of the voltage parameter M₀ and may determine whether there is a need to correct the estimated SOC.

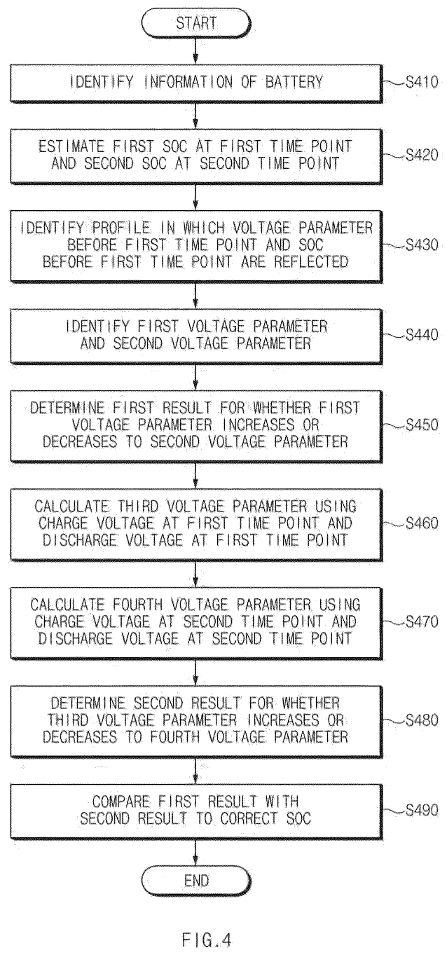

FIG. 4 is a flowchart for describing a vehicle control apparatus or a vehicle control method according to an embodiment of the present disclosure.

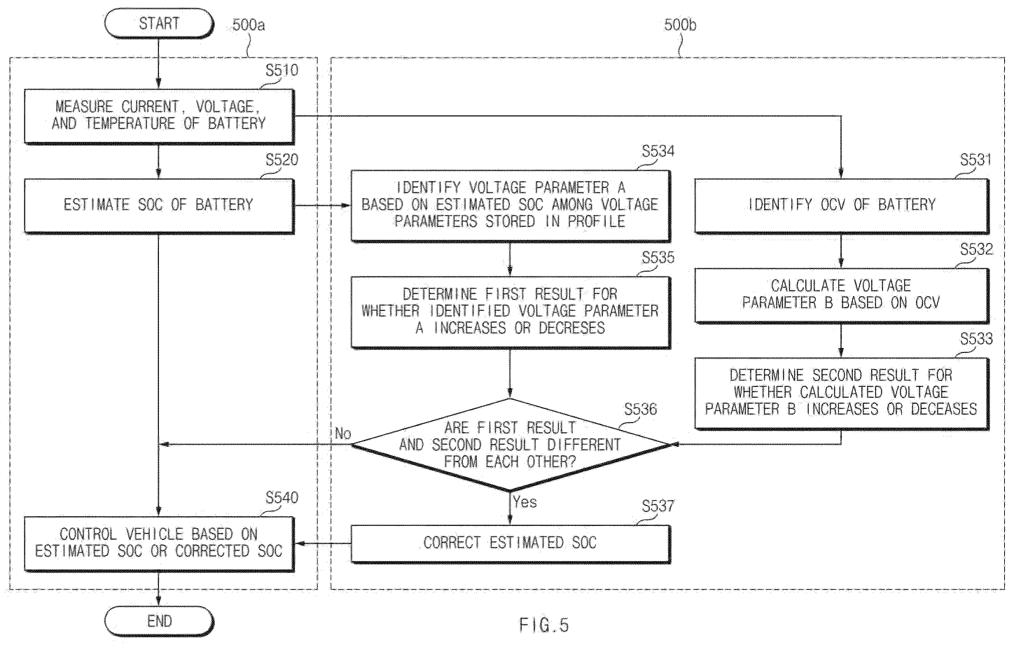

Hereinafter, a description will be given in detail of a vehicle control apparatus or a vehicle control method according to an embodiment of the present disclosure with reference to FIGS. 4 and 5.

Hereinafter, it is assumed that a vehicle control apparatus 100 of FIG. 1 performs a process of FIG. 4 or 5. Furthermore, in a description of FIG. 4 or 5, an operation described as being performed by a processor of a vehicle control apparatus may be understood as being controlled by a processor 110 of the vehicle control apparatus 100.

According to an embodiment, in S410, the processor of the vehicle control apparatus may identify information of a battery. For example, the information of the battery may include at least one of a charge current of the battery of a vehicle, a discharge current of the battery, a charge voltage of the battery, a discharge voltage of the battery, or a temperature of the battery, or any combination thereof.

According to an embodiment, in S420, the processor of the vehicle control apparatus may estimate a first SOC at a first time point and a second SOC at a second time point. For example, based on the information of the battery, the processor may estimate the first SOC of the battery at the first time point and may estimate the second SOC of the battery at the second time point when a certain time elapses from the first time point.

According to an embodiment, in S430, the processor of the vehicle control apparatus may identify a profile in which a voltage parameter before the first time point and an SOC before the first time point are reflected. For example, a charge voltage and a discharge voltage may be identified in a process in which the battery of the vehicle is charged or discharged, before the first time point. The voltage parameter may be calculated using the charge voltage and the discharge voltage, which are identified before the first time point. The calculated voltage parameter before the first time point may be reflected in the profile. In this case, the voltage parameter before the first time point may be reflected in the profile together with the SOC. Thus, the processor of the vehicle control apparatus may identify the profile in which the voltage parameter before the first time and the SOC before the first time are reflected.

According to an embodiment, in S440, the processor of the vehicle control apparatus may identify a first voltage parameter and a second voltage parameter.

For example, the processor may identify the first voltage parameter, based on the estimated first SOC and the profile. In detail, the processor may identify a voltage parameter corresponding to the first SOC among voltage parameters included in the profile.

For example, the processor may identify the second voltage parameter, based on the estimated second SOC and the profile. In detail, the processor may identify a voltage parameter corresponding to the second SOC among the voltage parameters included in the profile.

According to an embodiment, in S450, the vehicle device may determine a first result for whether the first voltage parameter increases or decreases to the second voltage parameter.

For example, if the identified first voltage parameter is smaller than the second voltage parameter, the processor may determine the first result that the voltage parameter increases.

According to an embodiment, in S460, the processor of the vehicle control apparatus may calculate a third voltage parameter using the charge voltage at the first time point and the discharge voltage at the first time point.

For example, the processor may calculate the third voltage parameter at the first time point, using the charge voltage at the first time point and the discharge voltage at the first time point. In detail, the third voltage parameter may be calculated by Equation 1 or 2 described above in the description of FIG. 1.

According to an embodiment, in S470, the processor of the vehicle control apparatus may calculate a fourth voltage parameter using the charge voltage at the second time point and the discharge voltage at the second time point.

For example, the processor may calculate the fourth voltage parameter at the second time point, using the charge voltage at the second time point and the discharge voltage at the second time point. In detail, the fourth voltage parameter may be calculated by Equation 1 or 2 described above in the description of FIG. 1.

According to an embodiment, in S480, the vehicle device may determine a second result for whether the third voltage parameter increases or decreases to the fourth voltage parameter.

For example, if the identified third voltage parameter is greater than the fourth voltage parameter, the processor may determine the second result that the voltage parameter decreases.

According to an embodiment, the processor of the vehicle control apparatus may compare the first result with the second result to correct the SOC.

For example, if the first result and the second result are different from each other, the processor may correct the estimated SOC. As a detailed example, if the first result is a result that the voltage parameter increases and the second result is a result that the voltage parameter decreases, the processor may correct the estimated SOC. In this case, the corrected SOC may include at least one of the first SOC or the second SOC, or any combination thereof.

FIG. 5 is a flowchart for describing in detail an example of a process of determining whether there is a need to correct an estimated SOC, in a vehicle control apparatus or a vehicle control method according to an embodiment of the present disclosure.

FIG. 5 according to an embodiment may include a process 500a of estimating an SOC of a battery and a process 500b of correcting the SOC of the battery.

According to an embodiment, in S510, the vehicle control apparatus may measure at least one of a current of the battery, a voltage of the battery, or a temperature of the battery, or any combination thereof by means of a sensor. The processor may identify information of the battery, which includes at least one of a current of the battery, a voltage of the battery, or a temperature of the battery, or any combination thereof.

According to an embodiment, in S520, a processor of the vehicle control apparatus may estimate an SOC of the battery, using at least one of the current of the battery, the voltage of the battery, or the temperature of the battery, or any combination thereof. For example, the processor may estimate the SOC of the battery, using a current integration method, a voltage measurement method, a chemometric method, a pressure measurement method, or the like. As a detailed example, the processor may estimate a first SOC at a first time point and a second SOC at a second time point.

According to an embodiment, in S534, the processor of the vehicle control apparatus may identify a voltage parameter A based on the estimated SOC among voltage parameters stored in a profile. For example, the processor may identify the first voltage parameter A corresponding to the first SOC and the second voltage parameter A corresponding to the second SOC.

According to an embodiment, in S535, the processor of the vehicle control apparatus may determine a first result for whether the identified voltage parameter A increases or decreases. For example, if it is identified that the first voltage parameter A is greater than the second voltage parameter A, the processor may determine the first result that the voltage parameter A decreases.

According to an embodiment, in S531, the processor of the vehicle control apparatus may identify an open circuit voltage (OCV) of the battery. For example, the processor may identify a charge OCV and a discharge OCV of the battery. As a detailed example, the processor may identify a charge OCV and a discharge OCV at the first time point and a charge OCV and a discharge OCV at the second time point.

According to an embodiment, in S532, the processor of the vehicle control apparatus may calculate a voltage parameter B based on the OCV. For example, the processor of the vehicle control apparatus may calculate the third voltage parameter B at the first time point and the fourth voltage parameter B at the second time point.

According to an embodiment, in S533, the processor of the vehicle control apparatus may determine a second result for whether the identified voltage parameter B increases or decreases. For example, if it is identified that the third voltage parameter B is smaller than the fourth voltage parameter B, the processor may determine the second result that the voltage parameter B increases.

According to an embodiment, in S536, the processor of the vehicle control apparatus may determine whether the first result and the second result are different from each other.

According to an embodiment, if the first result and the second result are different from each other, in S537, the processor of the vehicle control apparatus may correct the estimated SOC.

On the other hand, if the first result and the second result are not different from each other, the processor may fail to correct the estimated SOC.

According to an embodiment, in S540, the processor of the vehicle control apparatus may control a vehicle based on the estimated SOC and the corrected SOC. For example, if the first result and the second result are different from each other, the processor of the vehicle control apparatus may control the vehicle based on the corrected SOC. On the other hand, if the first result and the second result are not different from each other, the processor of the vehicle control apparatus may control the vehicle based on the estimated SOC.

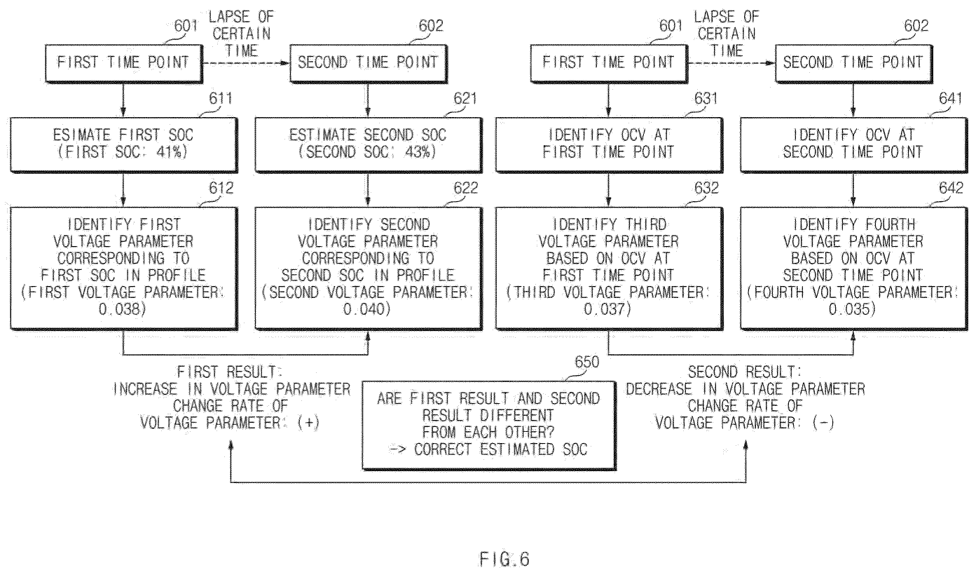

FIG. 6 is a drawing for describing an example of a method for comparing change rates of a voltage parameter in a vehicle control apparatus according to an embodiment of the present disclosure.

Hereinafter, a vehicle control apparatus 100 of FIG. 1 performs a process of FIG. 6. Furthermore, in a description of FIG. 6, an operation described as being performed by a processor may be understood as being controlled by a processor 110 of a vehicle control apparatus 100.

According to an embodiment, in operation 611, the processor may estimate a first SOC at a first time point 601. For example, the first SOC may be calculated by a current integration method using the current of a battery. As a detailed example, the first SOC may be estimated as 41%.

According to an embodiment, in operation 612, the processor may identify a first voltage parameter corresponding to the first SOC in a profile. For example, the first voltage parameter corresponding to an SOC of 41% in the profile may be identified as 0.038.

According to an embodiment, in operation 621, the processor may estimate a second SOC at a second time point 602. For example, the second SOC may be calculated by the current integration method using the current of the battery. As a detailed example, the second SOC may be estimated as 43%.

According to an embodiment, in operation 622, the processor may identify a second voltage parameter corresponding to the second SOC in the profile. For example, the second voltage parameter corresponding to an SOC of 43% in the profile may be identified as 0.040.

According to an embodiment, the processor may compare the first voltage parameter with the second voltage parameter and may determine whether the voltage parameter corresponding to the estimated SOC increases or decreases, while time elapses from the first time point 601 to the second time point 602.

For example, if the first voltage parameter is identified as 0.038 and the second voltage parameter is identified as 0.040, the processor may determine a first result that the voltage parameter increases. In this case, the processor may determine that a change rate of the voltage parameter is a positive number.

According to an embodiment, in operation 631, the processor may identify an open circuit voltage (OCV) at the first time point 601. For example, the processor may identify the OCV, based on information of the battery, which includes a current, a voltage, a temperature, or the like at the first time point 601. At this time, the first time point 601 may refer to the same time point as a time point when the above-mentioned first SOC is estimated.

According to an embodiment, in operation 632, the processor may identify a third voltage parameter, based on the OCV at the first time point 601. For example, the processor may calculate the third voltage parameter, based on Equation 1 or 2 described above in the above-mentioned description of FIG. 1. As a detailed example, the third voltage parameter may be calculated as 0.037.

According to an embodiment, in operation 641, the processor may identify an open circuit voltage (OCV) at the second time point 602. For example, the processor may identify the OCV, based on the information of the battery, which includes a current, a voltage, a temperature, or the like at the second time point 602. At this time, the second time point 602 may refer to the same time point as a time point when the above-mentioned second SOC is estimated.

According to an embodiment, in operation 642, the processor may calculate a fourth voltage parameter, based on the OCV at the second time point 602. For example, the processor may calculate the fourth voltage parameter, based on Equation 1 or 2 described above in the description of FIG. 1. As a detailed example, the fourth voltage parameter may be calculated as 0.035.

According to an embodiment, the processor may compare the third voltage parameter with the fourth voltage parameter and may determine whether the voltage parameter calculated by the OCV increases or decreases, while time elapses from the first time point 601 to the second time point 602.

For example, if the third voltage parameter is identified as 0.037 and the fourth voltage parameter is identified as 0.035, the processor may determine a second result that the voltage parameter decreases. In this case, the processor may determine that a change rate of the voltage parameter is a negative number.

According to an embodiment, in operation 650, the processor may compare the first result with the second result. For example, if the first result and the second result are different from each other, the processor may correct the estimated SOC. As a detailed example, if the first result is a result determined that the change rate of the voltage parameter is a positive number and the second result is a result determined that the change rate of the voltage parameter is a negative number, because the first result and the second result are different from each other, the processor may correct the estimated SOC. At this time, the processor may correct the SOC, such that the first result is able to be the same result as the second result. The processor may control a vehicle based on the corrected SOC.

According to an embodiment, if the first result and the second result are the same as each other, the processor may fail to correct the estimated SOC. In this case, the processor may control the vehicle based on the estimated SOC.

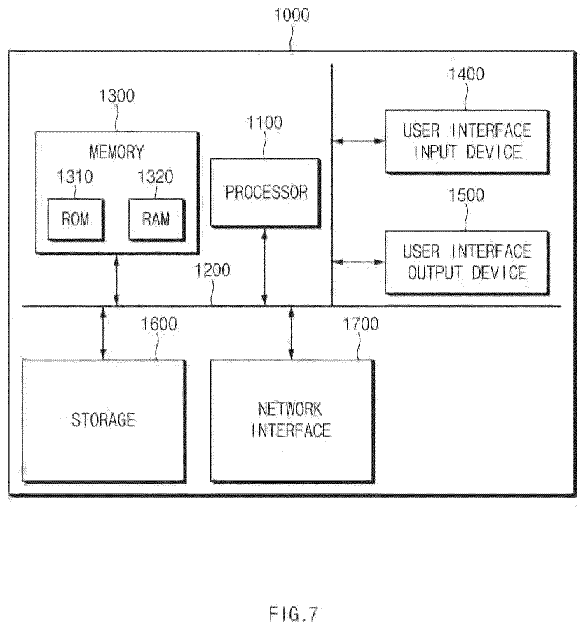

FIG. 7 is a drawing illustrating a computing system associated with a vehicle control apparatus or a vehicle control method according to an embodiment of the present disclosure.

Referring to FIG. 7, a computing system 1000 may include at least one processor 1100, a memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Accordingly, the operations of the method or algorithm described in connection with the embodiments disclosed in the specification may be directly implemented with a hardware module, a software module, or a combination of the hardware module and the software module, which is executed by the processor 1100. The software module may reside on a storage medium (that is, the memory 1300 and/or the storage 1600) such as a RAM, a flash memory, a ROM, an EPROM, an EEPROM, a register, a hard disc, a removable disk, and a CD-ROM.

The exemplary storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The present technology may improve the accuracy of estimation of a battery SOC using a hysteresis characteristic of a charge voltage and a discharge voltage of the battery.

In detail, the present technology may overcome a limitation which occurs to estimate an SOC of an LFP battery as a change in open circuit voltage (OCV) according to the SOC is small, using a hysteresis characteristic of the OCV.

Furthermore, the present technology may correct an error which occurs in an SOC of the battery, which is estimated in a current integration method, using the hysteresis characteristic of the OCV.

In addition, various effects ascertained directly or indirectly through the present disclosure may be provided.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A vehicle control apparatus, comprising:
a memory storing a program instruction; and
a processor configured to execute the program instruction,
wherein the processor is configured to:
identify information of a battery of a vehicle, the information including at least one of a charge current of the battery, a discharge current of the battery, a charge voltage of the battery, a discharge voltage of the battery, or a temperature of the battery;
estimate a first state of charge (SOC) of the battery at a first time point and a second SOC of the battery at a second time point when a certain time elapses from the first time point, based on the information of the battery;
calculate a voltage parameter and an SOC of the battery, the voltage parameter and the SOC being calculated according to a hysteresis characteristic of a charge voltage and a discharge voltage, so as to determine a profile of the battery;
identify a first voltage parameter, based on the profile and the first SOC;
identify a second voltage parameter, based on the profile and the second SOC;
determine a first result for whether the first voltage parameter increases or decreases to the second voltage parameter;
calculate a third voltage parameter according to the hysteresis characteristic of the battery, using the charge voltage at the first time point and the discharge voltage at the first time point;
calculate a fourth voltage parameter according to the hysteresis characteristic of the battery, using the charge voltage at the second time point and the discharge voltage at the second time point;
determine a second result for whether the third voltage parameter increases or decreases to the fourth voltage parameter, and
compare the first result with the second result and correct at least one of the first SOC or the second SOC.

2. The vehicle control apparatus of claim 1, wherein the processor is configured to:
correct the at least one of the first SOC or the second SOC, based on determination that the first result and the second result are different from each other.

3. The vehicle control apparatus of claim 1, wherein the processor is configured to:
correct the at least one of the first SOC or the second SOC, upon determining that the first result and the second result are the same as each other.

4. The vehicle control apparatus of claim 1, wherein the profile includes information in which the SOC and the voltage parameter match with each other, and
wherein the processor is configured to:
identify a point at which a change rate of the voltage parameter according to the SOC is 0, based on the information in which the SOC and the voltage parameter match with each other.

5. The vehicle control apparatus of claim 4, wherein the processor is configured to:
identify at least one third SOC corresponding to the point at which the change rate of the voltage parameter according to the SOC is 0 among a plurality of SOCs included in the profile; and
determine the first result, based on that the third SOC is not included between the first SOC and the second SOC.

6. The vehicle control apparatus of claim 1, wherein the processor is configured to:
update the profile based on the information of the battery.

7. The vehicle control apparatus of claim 6, wherein the processor is configured to:
update a point at which a change rate of the voltage parameter according to the SOC is 0 among points included in the profile, based on the information of the battery.

8. The vehicle control apparatus of claim 1, wherein the processor is configured to:
identify the charge voltage or the discharge voltage, based on an open circuit voltage (OCV).

9. A vehicle comprising the vehicle control apparatus of claim 1.

10. The vehicle control apparatus of claim 1, wherein the processor is configured to:
store the profile in at least one of the memory, a storage device of the vehicle, the storage device being different from the memory, or an external server.

11. The vehicle control apparatus of claim 1, wherein the processor is configured to:
provide a user with information about at least one of the corrected first SOC or the corrected second SOC, by at least one of a display of the vehicle or an audio of the vehicle.

12. A vehicle control method, comprising:
identifying, by a processor, information of a battery of a vehicle, the information including at least one of a charge current of the battery, a discharge current of the battery, a charge voltage of the battery, a discharge voltage of the battery, or a temperature of the battery;
estimating, by the processor, a first state of charge (SOC) of the battery at a first time point and a second SOC of the battery at a second time point when a certain time elapses from the first time point, based on the information of the battery;
calculating, by the processor, a voltage parameter and an SOC of the battery, the voltage parameter and the SOC being calculated according to a hysteresis characteristic of a charge voltage and a discharge voltage, so as to determine a profile of the battery;
identifying, by the processor, a first voltage parameter, based on the profile and the first SOC;
identifying, by the processor, a second voltage parameter, based on the profile and the second SOC;
determining, by the processor, a first result for whether the first voltage parameter increases or decreases to the second voltage parameter;
calculating, by the processor, a third voltage parameter according to the hysteresis characteristic of the battery, using the charge voltage at the first time point and the discharge voltage at the first time point;
calculating, by the processor, a fourth voltage parameter according to the hysteresis characteristic of the battery, using the charge voltage at the second time point and the discharge voltage at the second time point;
determining, by the processor, a second result for whether the third voltage parameter increases or decreases to the fourth voltage parameter, and
comparing, by the processor, the first result with the second result and correcting, by the processor, at least one of the first SOC or the second SOC.

13. The vehicle control method of claim 12, wherein the comparing of the first result with the second result by the processor and the correcting of the at least one of the first SOC or the second SOC, or the any combination thereof by the processor includes:
correcting, by the processor, the at least one of the first SOC or the second SOC, or the any combination thereof, based on determination that the first result and the second result are different from each other.

14. The vehicle control method of claim 12, wherein the comparing of the first result with the second result by the processor and the correcting of the at least one of the first SOC or the second SOC, or the any combination thereof by the processor includes:
correcting, by the processor, the at least one of the first SOC or the second SOC, or the any combination thereof to be determined that the first result and the second result are the same as each other.

15. The vehicle control method of claim 12, wherein the determining of the first result for whether the first voltage parameter increases or decreases to the second voltage parameter by the processor includes:
identifying, by the processor, a point at which a change rate of the voltage parameter according to the SOC is 0, based on information in which the SOC and the voltage parameter match with each other, the information being included in the profile.

16. The vehicle control method of claim 15, wherein the determining of the first result for whether the first voltage parameter increases or decreases to the second voltage parameter by the processor includes:
identifying, by the processor, at least one third SOC corresponding to the point at which the change rate of the voltage parameter according to the SOC is 0 among a plurality of SOCs included in the profile; and
determining, by the processor, the first result, based on that the third SOC is not included between the first SOC and the second SOC.

17. The vehicle control method of claim 12, further comprising:
updating, by the processor, the profile based on the information of the battery.

18. The vehicle control method of claim 17, wherein the updating of the profile based on the information of the battery by the processor includes:
updating, by the processor, a point at which a change rate of the voltage parameter according to the SOC is 0 among points included in the profile, based on the information of the battery.

19. The vehicle control method of claim 12, wherein the identifying of the information of the battery of the vehicle, the information including the at least one of the charge current of the battery, the discharge current of the battery, the charge voltage of the battery, the discharge voltage of the battery, or the temperature of the battery, or the any combination thereof by the processor includes:
identifying, by the processor, the charge voltage or the discharge voltage, based on an open circuit voltage (OCV).

20. The vehicle control method of claim 12, further comprising:
storing, by the processor, the profile in at least one of a memory, a storage device of the vehicle, the storage device being different from the memory, or an external server.
